(19) United States
(12) Patent Application Publication
(10) Pub. No.: US 2024/0340022 A1
(43) Pub. Date: Oct. 10, 2024

(54) Digital-to-Analog Conversion Circuit

(71) Applicant: Nippon Telegraph and Telephone Corporation, Tokyo (JP)

(72) Inventors: Masayuki Hashisaka, Musashino-shi, Tokyo (JP); Norio Kumada, Musashino-shi, Tokyo (JP)

(21) Appl. No.: 18/294,896

(22) PCT Filed: Aug. 17, 2021
(86) PCT No.: PCT/JP2021/030030

§ 371 Date: Feb. 2, 2024

(51) Int. Cl. H03M 1/78

(52) U.S. Cl. CPC H03M 1/785

(57) ABSTRACT

A digital-to-analog conversion circuit having high resolution is constituted by including a quantum Hall element having a resistance value R, a quantum Hall element pair having a resistance value 2R, a quantum Hall element connected to a node between the quantum Hall element and the quantum Hall element pair, and a switch which supplies any of a plurality of voltages (input voltage or ground voltage) having different values to a terminal different from a terminal of the quantum Hall element of a side connected to the node, in which at least a part of the quantum Hall element, the quantum Hall element pair, and the switch is used as a quantum Hall element whose resistance value is quantized by applying a magnetic field.

### TECHNICAL FIELD

The present invention relates to a digital-to-analog conversion circuit.

### BACKGROUND ART

Data converters for converting digital signals into analog signals or analog signals into digital signals are used in various fields in electronic circuits. A data converter is described in, for example, NPL 1. NPL 1 describes, as an example of a digital-to-analog conversion circuit, an example that digitizes and processes analog touch and voice signals in a smartphone, converts them back to analog signals, and transmits them to a base station or the like. Regarding such digital-to-analog conversion of such processing, the higher the minimum value of the digital signal that can be represented by the analog signal after conversion, that is, the resolution is, the more an operational accuracy of a smartphone and voice reproducibility thereof can be improved.

An R-2R ladder circuit having an advantage of being easily manufactured and having a relatively small size is known as a digital-analog conversion circuit. In the R-2R ladder circuit, a plurality of resistance elements having a resistance value R and a plurality of resistance elements having a resistance value 2R are regularly disposed, and a terminal connected to the switch is connected to either an input voltage V or a ground (voltage 0). That is, the R-2R ladder circuit converts digital signals D₀, D₁, . . . Dₙ₋₁ into n-bit analog voltage signals. In many cases, practically, the R-2R ladder circuit is used in such a manner that a buffer circuit such as an operational amplifier is connected to an output terminal to output sufficient current.

### CITATION LIST

### Non Patent Literature

[NPL 1]“Introduction to Digital/Analog Conversion” by Takao Waho, CORONA PUBLISHING CO., LTD.

### SUMMARY OF INVENTION

The resolution of the R-2R ladder circuit is determined by the relative accuracy (specific accuracy) of the resistance value (circuit constant) of the resistance element included in the circuit. In order to improve the resolution of the R-2R ladder circuit, the resistance values (R and 2R) of the resistance elements also including the contribution of the parasitic resistance of the switch and wiring are accurately aligned, thereby realizing a high-resolution digital-analog conversion circuit. However, it is difficult to sufficiently reduce the variation of the resistance value of the resistance element depending on the conditions of the process when manufacturing the resistance elements, and it is desired to further improve the specific accuracy of the resistance values in the R-2R ladder circuit. The present disclosure has been made in view of such a point, and an object of the present disclosure is to provide a digital-to-analog conversion circuit having a higher resolution.

To achieve the above object, a digital-to-analog conversion circuit according to an embodiment of the present disclosure includes a first element having a first resistance value; a second element having a second resistance value different from the first resistance value; a third element connected to a node between the first element and the second element; and a switch element which supplies any one of a plurality of voltages having different values to a terminal different from a terminal of the third element on a side connected to the node, in which at least a part of the first element, the second element, the third element, and the switch element is a quantum Hall element whose resistance value is quantized by applying a magnetic field.

According to the above-described configuration, it is possible to provide a digital-to-analog conversion circuit having a higher resolution.

### BRIEF DESCRIPTION OF DRAWINGS

FIG. 1 is a cross-sectional view illustrating a sample of a general quantum Hall element.

FIG. 2 is a diagram showing a well-known R-2R ladder circuit of n bits.

FIG. 3 is a diagram for explaining a R-2R ladder circuit of a first embodiment of the present invention.

FIG. 4 is a perspective view for explaining the quantum Hall element shown in FIG. 3 in more detail.

FIG. 5 is a diagram for explaining a R-2R ladder circuit of a second embodiment.

FIG. 6 is a perspective view for explaining the quantum Hall element in detail.

### DESCRIPTION OF EMBODIMENTS

In the first and second embodiments of the present invention, a quantum Hall effect or an abnormal quantum Hall effect is utilized for a digital-analog circuit of an R-2R ladder circuit to enhance specific accuracy and realize high resolution. Here, the quantum Hall effect refers to a phenomenon in which Hall conductivity of a two-dimensional electron system is quantized when a magnetic field is applied perpendicularly to a sample (two-dimensional electron system) in which electrons are distributed two-dimensionally. The magnetic field may be applied using an electromagnet or a permanent magnet. The abnormal quantum Hall effect is a phenomenon in which the quantization of Hall conductivity occurs in a two-dimensional electron system having magnetism without a magnetic field. As examples of two-dimensional electron-based samples which exhibit quantum Hall effects, various types of samples such as semiconductor heterointerfaces, atomic layer materials such as graphene, and surfaces of compounds are known. In the present specification, the quantum Hall effect and the abnormal quantum Hall effect are collectively described as a quantum Hall effect, and an element in the quantum Hall effect state is referred to as a quantum Hall element.

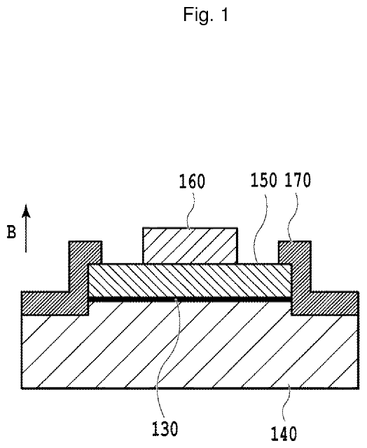

Here, prior to the first embodiment, the quantum Hall element will be described. FIG. 1 is a cross-sectional view illustrating a sample of a general quantum Hall element. The quantum Hall element shown in FIG. 1 has a substrate of gallium arsenide (GaAs) 140, and an aluminum gallium arsenide layer 150 (AlₓGa₁₋ₓAs, x represents a proportion of gallium substituted with aluminum, and typically is about x=0.3). Electrons are accumulated in a portion of a heterointerface 130 between the substrate 140 and the aluminum gallium arsenide layer 150. In the present specification, not only an interface between the substrate and the layer in which electrons are accumulated, but also the interface in which electrons are accumulated, and the substrate and the semiconductor layer constituting the interface are referred to as “two-dimensional electron system”. In the sample shown in FIG. 1, two metal electrodes 170 are brought into contact with the two-dimensional electron system to form electrode terminals. When a voltage is applied to one of the metal electrodes 170 and a current is measured in the other metal electrode 170, the electric resistance of the two-dimensional electron system can be measured.

In such a sample, when a perpendicular magnetic field B in a direction shown in FIG. 1 is applied, a quantum Hall effect occurs, and the electric resistance between the two electrode terminals is quantized. As shown in FIG. 1, a metal gate electrode 160 can be attached to the aluminum gallium arsenide layer 150. Since the gate electrode 160 and the aluminum gallium arsenide layer 150 are insulated by a Schottky barrier, a gate voltage can be applied to a sample having the gate electrode 160. Although gold is often used for the gate electrode 160, any metal may be used in principle as long as it is a material that generates a Schottky barrier. Since the electrons constituting the two-dimensional electron system have negative charges, when a negative gate voltage is applied, a repulsive force is generated between the electrons and the gate electrode, and as a result, the electron density of the two-dimensional electron system immediately below the gate electrode decreases. When a larger negative gate voltage is applied, the electron density of the two-dimensional electron system immediately below is made zero and the two-dimensional electron system can be insulated (a depletion layer is formed).

Although the above description is directed to a two-dimensional electron system at the hetero interface between GaAs and AlₓGa₁₋ₓAs, the quantum Hall effect is a phenomenon which occurs in principle in any two-dimensional electron system. Therefore, the quantum Hall element of the present disclosure is not limited to a configuration including a hetero interface between the GaAs semiconductor substrate and the AlₓGa₁₋ₓAs layer. Examples of the semiconductor material used in the quantum Hall device include indium arsenic (InAs) and indium antimony (InSb). Further, the materials and the element structure of the gate electrode 160 and the metal electrode 170 of the quantum Hall element need to be appropriately selected in accordance with the selected two-dimensional electron-based material. For example, in the case of manufacturing a quantum Hall element by forming an InAs layer on a substrate, the metal electrode 170 is provided after an insulating layer of alumina or the like is provided. In the case of an atomic layer material such as graphene, since the two-dimensional electron system is exposed, it is necessary to provide an insulating layer.

### First Embodiment

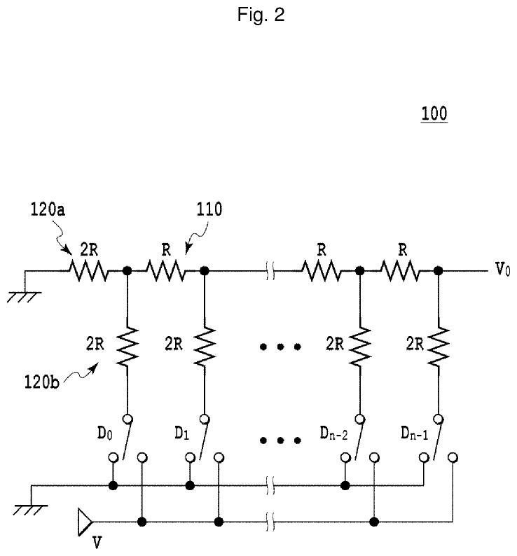

FIG. 2 shows a well-known R-2R ladder circuit 100 of n bits. The R-2R ladder circuit 100 includes resistance elements 110, 120a and 120b, and a plurality of switches D₀ to Dₙ₋₁. The resistance value of the resistance element 110 is defined as R, and the resistance values of the resistance elements 120a and 120b are defined as 2R. The R-2R ladder circuit divides a reference voltage V by the resistance value of R-2R, and outputs a current to which each weight is added. The R-2R ladder circuit 100 is configured so that resistance elements 110 and 120a are connected between a ground voltage and an input voltage V, a resistance element 120b is connected between the resistance element 110 and the resistance element 120a, and the resistance element 120b is connected to one of the ground voltage and the input voltage V by switches D₀ to Dₙ₋₁.

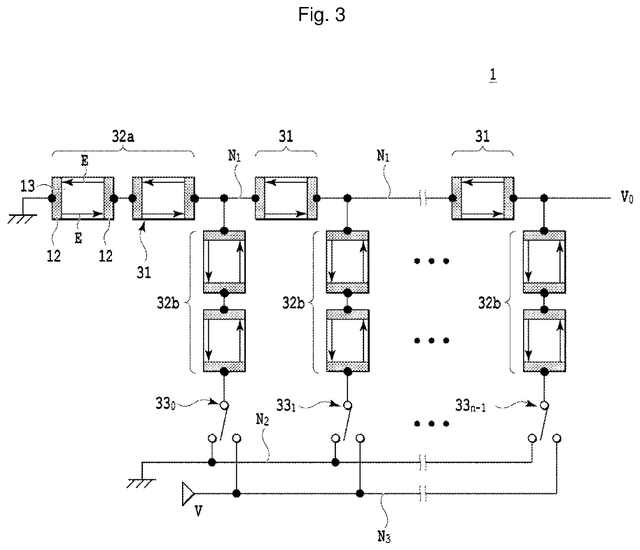

FIG. 3 is a diagram for explaining the R-2R ladder circuit 1 of the first embodiment of the present invention. In the R-2R ladder circuit 1 of the first embodiment, a quantum Hall element 31 is used in place of the resistance elements 110, 120a and 120b shown in FIG. 1. The quantum Hall element 31 shown in FIG. 3 corresponds to the resistance element 110 shown in FIG. 1, a quantum Hall element pair 32a made up of the two quantum Hall elements 31 corresponds to the resistance element 120a, and a quantum Hall element pair 32b corresponds to the resistance element 120b. That is, the R-2R ladder circuit 1 has quantum Hall element pairs 32a and 32b having a resistance value twice the resistance value of the quantum Hall element 31 by connecting the quantum Hall elements 31 in series. The quantum Hall element 31 and the quantum Hall element pair 32a are connected in series. In the quantum Hall element 31, a terminal on the opposite side to a terminal connected to the quantum Hall element pair 32a is sequentially connected in series with the plurality of other quantum Hall elements 31. The quantum Hall element pair 32b is connected to each node N₁ between the quantum Hall element pair 32 and the quantum Hall element 31, and between the quantum Hall elements 31. A switch 33 is connected to the opposite side to the side connected to the node N₁ of the quantum Hall element pair 32b. One switch 33 is connected to each of the nodes N₁ at a plurality of places, and a plurality of switches 33₀ to 33ₙ₋₁ are provided in the whole R-2R ladder circuit 1. When it is not necessary to distinguish the switches 33₀ to 33ₙ₋₁, the switches are simply referred to as the switch 33.

In the aforementioned configuration, the quantum Hall element 31 corresponds to a first element, the quantum Hall element pair 32a corresponds to a second element, and the quantum Hall elements 32b connected between the quantum Hall element 31 and the quantum Hall element pair 32a and parallel to each other corresponds to a third element. The switch 33 corresponds to a switch element.

Furthermore, the R-2R ladder circuit 1 includes a node N₂ to which a ground voltage is applied, and a node N₃ to which an input voltage V is applied. The switch 33 is switched so that quantum Hall element pairs 32b connected in parallel to each other is connected to either a ground voltage or a reference voltage. In such a configuration, when a binary digital signal (0 or 1) is input to each switch 33b, input of 0 is grounded, and input of 1 is made to correspond to connection to an input voltage V, output voltage Vₒ=V×(D₀×2⁰+D₁×2¹+ . . . +Dₙ₋₁×2ⁿ¹)/2ⁿ is output by the binary digital signals D₀, D₁, . . . Dₙ₋₁.

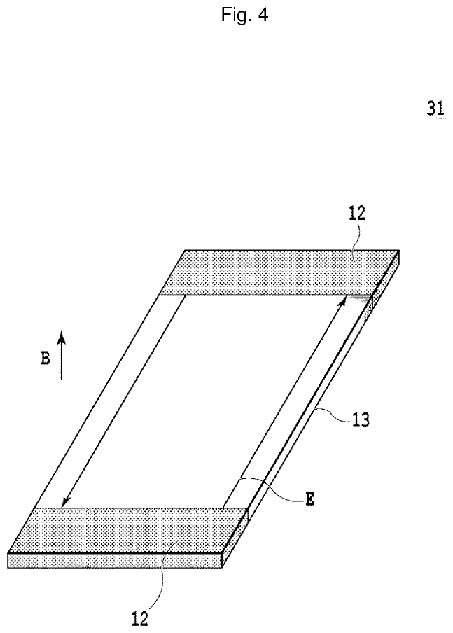

FIG. 4 is a perspective view for explaining the quantum Hall element 31 shown in FIG. 3 in more detail. The quantum Hall element 31 shown in FIG. 4 includes a two-dimensional electron system 13 and metal electrodes 12 provided at both ends of the two-dimensional electron system 13. A vertical magnetic field B is applied to the quantum Hall element 31, and the resistance between the metal electrodes 12 is in a quantized state. The application of the vertical magnetic field can be provided, for example, by disposing a stage on which the quantum Hall element 31 is set in the line of magnetic force generated from the magnet, and by setting the quantum Hall element 31 so that the line of magnetic force passes vertically through a main surface of the quantum Hall element 31. The magnets may be permanent magnets or electromagnets.

The example shown in FIG. 4 is a quantum Hall element configured to have no gate electrode. In the first embodiment, the two-dimensional electron system 13 can be configured, for example, by forming an AlGaAs layer on one main surface side of a GaAs substrate. The inside (bulk) of the two-dimensional electron system 13 is an insulator, and a current flows along a one-dimensional unidirectional conduction channel (edge channel) E generated at the outer edge of the two-dimensional electron system 13. The electric conductivity of the quantum Hall element 31 is determined mainly by the number n of edge channels E running in parallel at the end of the two-dimensional electron system 13, and the two-terminal resistance between the metal electrodes (between the metal electrodes 12 and 12 in the first embodiment) is determined by (R_{K}/n) obtained by dividing von Klitzing constant Rk by the number n of edge channels E. Since the two-terminal resistance is quantized very accurately, it is known to be utilized as an electric resistance standard (PHYSICAL MEASUREMENT LABORATORY, https://physics.nist.gov/cgi-bin/cuu/Value?rk) (accessed on Aug. 6, 2021)).

The number n of edge channels is determined by the ratio of the electron density (the number of electrons per unit area) of the two-dimensional electron system to the intensity of the magnetic field (the number of magnetic flux quanta per unit area) (a Landau level filling rate n). Therefore, in the first embodiment, the value of the quantum Hall element resistance can be changed by adjusting the voltage applied to the semiconductor material such as the GaAs substrate or the AlGaAs layer and the metal electrode 12, and the intensity of the vertical magnetic field B.

Next, a description will be given of an increase in the specific accuracy of the R-2R ladder circuit 1 by constructing the R-2R ladder circuit 1 shown in FIG. 3 using the quantum Hall element 31.

A two-terminal resistance R_{QH} of the quantum Hall element 31 is expressed by the following formula.

R_{QH}═(R_{K}/n)+R_{c} formula (1)

In the formula (1), R_{c} represents a value of the contact resistance of the metal electrode 12 in contact with the layer constituting the two-dimensional electron system. In general, R_{c} is a sufficiently smaller value than (Rₖ/n), and the two-terminal resistance is dominated by an accurate value of (Rₖ/n). However, the value R_{c} of the contact resistance is varied in the manufacturing process, and it is difficult to eliminate this variation. In order to make the two-terminal resistances of a plurality of quantum Hall elements 31 of the R-2R ladder circuit 1 constant with higher accuracy, it is conceivable to form the R-2R ladder circuit 1, using the quantum Hall elements 31 formed on the same semiconductor wafer.

That is, most of the semiconductor elements are formed by defining a plurality of element regions on one semiconductor wafer, manufacturing a member necessary for the element in each of the element regions, and dividing the semiconductor wafer into chips after completion of the element. In such a process, the quantum Hall element 31 formed of the same semiconductor wafer can eliminate variations in the contact resistance derived from the substrate of the two-dimensional electron system 13, and can make the two-terminal resistance constant with high accuracy. Since the metal electrode 12 is formed by removing a single metal layer formed on the wafer by etching, the metal electrodes 12 of the plurality of quantum Hall elements 31 are formed of the same metal layer. In the plurality of quantum Hall elements 31 having the metal electrode 12 formed of the same metal layer, there is little variation in the contact resistance value R_{c} due to the thickness and composition of the metal layer, and the value R_{c} can be made constant with high accuracy.

Further, in the first embodiment, elements having different resistance values are formed in the R-2R ladder circuit 1, using only the quantum Hall element 31 having high specific accuracy of the two-terminal resistances. That is, in the first embodiment, since two quantum Hall elements 31 are connected in series to form one quantum Hall element pair 32, the specific accuracy of a plurality of quantum Hall element pairs 32 can be improved. Further, the specific accuracy of the whole quantum Hall element included in the R-2R ladder circuit 1 is enhanced, and a digital-analog circuit of high resolution can be constituted. However, the first embodiment is not limited to such a configuration, and elements other than quantum Hall elements can be used as resistance elements in a range in which specific accuracy is allowed.

As described above, in the first embodiment, by using the quantum Hall element 31 having extremely accurate and highly reproducible electrical conductivity as a resistor, a digital-to-analog conversion circuit having higher resolution than the related art can be realized. Furthermore, by using a plurality of quantum Hall elements formed on the same substrate in one R-2R ladder circuit, the dispersion of element characteristics caused by a process can be suppressed, the specific accuracy of the digital-analog circuit can be enhanced, and the resolution can be further enhanced.

Furthermore, the first embodiment is not limited to an aspect in which the R-2R ladder circuit is configured by the quantum Hall element 31 and the quantum Hall element pairs 32a and 32b including the two quantum Hall elements 31. In the first embodiment, a large number of quantum Hall elements 31 may be connected to form a digital-to-analog conversion circuit different from the R-2R ladder circuit.

### Second Embodiment

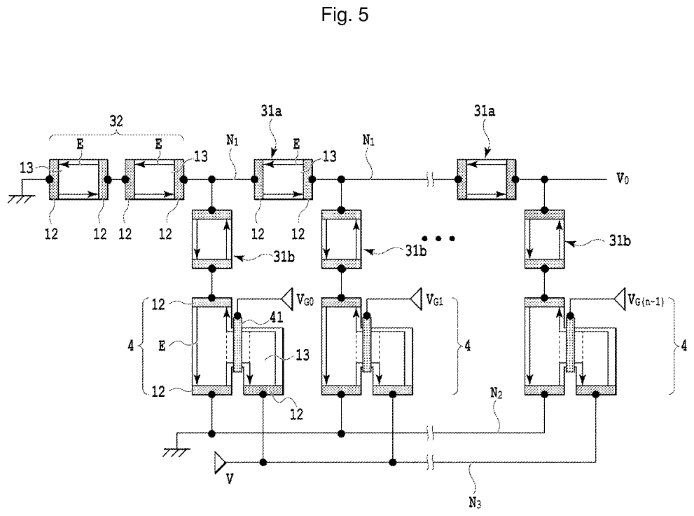

FIG. 5 is a diagram for explaining a R-2R ladder circuit 2 of a second embodiment. The R-2R ladder circuit 2 is a circuit in which a quantum Hall element 4 having a gate electrode is provided in place of the switch 33 of the R-2R ladder circuit 1 of the first embodiment. The quantum Hall element 4 functioning as a switch element insulates or makes a part under the gate electrode conductive by applying a voltage to the gate electrode.

In the R-2R ladder circuit 2, a plurality of quantum Hall element pairs 32 and quantum Hall elements 31a are connected in series, a quantum Hall element 31b is connected to a node N1 between the quantum Hall element pairs 32 and the quantum Hall element 31a, and the quantum Hall element 4 having a gate electrode 41 is connected to the quantum Hall element 31b. A plurality of nodes N1 between the quantum Hall element pair 32 and the quantum Hall element 31a are provided, the quantum Hall element 31b and the quantum Hall element 4 are connected in series to each of the plurality of nodes, and the quantum Hall elements 31b and the quantum Hall elements 4 are parallel to each other.

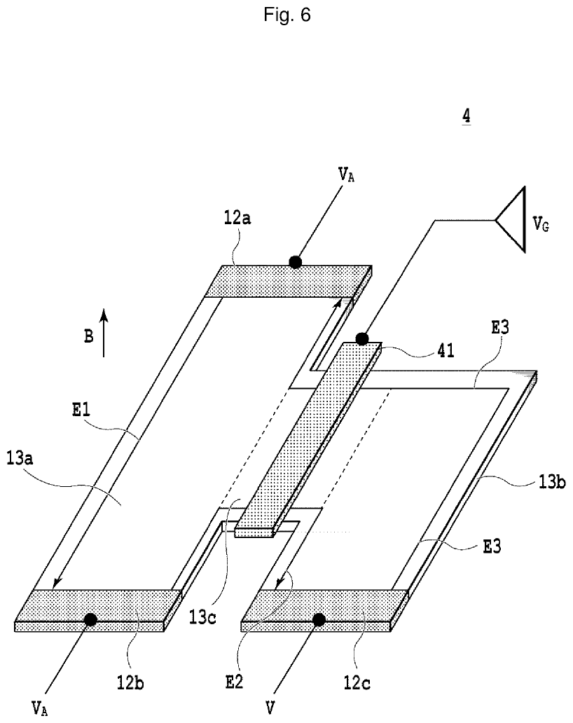

FIG. 6 is a perspective view for explaining the quantum Hall element 4 in more detail. The quantum Hall element 4 has two-dimensional electron systems 13a, 13b and 13c, a gate electrode 41 formed on the two-dimensional electron system 13c, metal electrodes 12a and 12b provided on the two-dimensional electron system 13a, and a metal electrode 12c provided on the two-dimensional electron system 13b. The metal electrode 12a is connected to the quantum Hall element 31b, and a ground voltage (denoted as V_{A} in the drawing) is applied thereto. A ground voltage is applied to the metal electrode 12b via a node N2. An input voltage V is applied to the metal electrode 12c via a node N3. A gate voltage V_{G} is applied to the gate electrode 41. The quantum Hall element 4 switches a voltage applied to the quantum Hall element by changing an electrode through which a current flows.

In the second embodiment, as described in FIG. 1, a negative gate voltage is applied to the gate electrode 41 to form a depletion layer at the interface under the gate electrode 41 to insulate the depletion layer. Thus, in the quantum Hall element 4, when the gate voltage V_{G} is not applied, the interface is made conductive, and a current corresponding to the potential difference between the voltage V_{A} and the input voltage V flows between the two-dimensional electron systems 13a and 13b through the edge channels E1, E2, and E3. Such a state corresponds to a state in which the switch 33 shown in FIG. 3 is connected to the input voltage side. When a gate voltage V_{G} is applied to the gate electrode 41, the two-dimensional electron system 13c is insulated, and no current flows between the two-dimensional electron system 13a and the two-dimensional electron system 13b. At this time, the current flows through the edge channel E1 and the edge channel from the metal electrode 12b to the metal electrode 12a parallel to the edge channel E1 (not shown). Such a state corresponds to a state in which the switch 33 shown in FIG. 3 is connected to the ground voltage side.

As described above, the digital-analog circuit of the second embodiment is constituted by the quantum Hall elements in addition to the resistance elements in the known R-2R ladder circuit. The digital-analog circuit of the second embodiment can further improve the specific accuracy of the elements by suppressing the variation of the regulating resistance caused by the switches, and can constitute a digital-analog circuit having higher resolution.

Further, in the second embodiment provided with a quantum Hall element having a gate electrode, the electron density of the interface can be changed by utilizing the gate voltage together with the semiconductor material and the vertical magnetic field B, and the number of edge channels can be controlled.

### REFERENCE SIGNS LIST

1, 2, 100 Ladder circuit
4, 31, 32, 31a, 31b, 32a, 32b Quantum Hall element
12, 12a, 12b, 12c, 170 Metal electrode
13, 13a, 13b, 13c Two-dimensional electron system
33 Switch
41, 160 Gate electrode
110, 120 Resistance element
130 Hetero interface
140 Substrate
150 Aluminum gallium arsenide layer

1. A digital-to-analog conversion circuit comprising:
a first element having a first resistance value;
a second element having a second resistance value different from the first resistance value;
a third element connected to a node between the first element and the second element; and
a switch element which supplies any one of a plurality of voltages having different values to a terminal different from a terminal of the third element on a side connected to the node,
wherein at least a part of the first element, the second element, the third element, and the switch element is a quantum Hall element whose resistance value is quantized by applying a magnetic field.

2. The digital-to-analog conversion circuit according to claim 1,
wherein the second element is configured by connecting the first elements in a plurality of series.

3. The digital-to-analog conversion circuit according to claim 1,
wherein a plurality of quantum Hall elements are provided, each of the plurality of quantum Hall elements constitutes a two-dimensional electron system by a semiconductor substrate and a layer of a semiconductor which is formed on one main surface side of the semiconductor substrate and in which electrons are accumulated between the semiconductor substrate and the layer of the semiconductor, the plurality of quantum Hall elements include an electrode that is in contact with the two-dimensional electron system, and the semiconductor substrate is cut out from the same semiconductor wafer.

4. The digital-to-analog conversion circuit according to claim 3,
wherein at least a part of the switching element is the quantum Hall element, the switching element includes a gate electrode on the layer of the semiconductor in the two-dimensional electron system, and the part under the gate electrode is insulated or made conductive by applying a voltage to the gate electrode.

5. The digital-to-analog conversion circuit according to claim 4,
wherein the switch element insulates or makes conductive the part under the gate electrode by applying a voltage to the gate electrode, and switches the voltage applied to the quantum Hall element by changing the electrode through which a current flows.

6. The digital-to-analog conversion circuit according to claim 2,
wherein a plurality of quantum Hall elements are provided, each of the plurality of quantum Hall elements constitutes a two-dimensional electron system by a semiconductor substrate and a layer of a semiconductor which is formed on one main surface side of the semiconductor substrate and in which electrons are accumulated between the semiconductor substrate and the layer of the semiconductor, the plurality of quantum Hall elements include an electrode that is in contact with the two-dimensional electron system, and the semiconductor substrate is cut out from the same semiconductor wafer.
